(19) United States
(12) Patent Application Publication
(10) Pub. No.: US 2013/0164445 A1
(43) Pub. Date: Jun. 27, 2013

(54) Self-Contained Heating Element

(71) Applicants: Garry K. Kwong, San Jose, CA (US); Joseph Yudovsky, Campbell, CA (US); Steven D. Marcus, San Jose, CA (US)

(72) Inventors: Garry K. Kwong, San Jose, CA (US); Joseph Yudovsky, Campbell, CA (US); Steven D. Marcus, San Jose, CA (US)

(21) Appl. No.: 13/720,301

(22) Filed: Dec. 19, 2012

Related U.S. Application Data
(60) Provisional application No. 61/579,762, filed on Dec. 23, 2011.

(51) Int. Cl. C23C 16/448

(52) U.S. Cl. CPC C23C 16/448
USPC 427/255.5; 392/485

(57) ABSTRACT

Provided are assemblies comprising an elongate enclosure comprising a material resistant to thermal expansion at temperatures experienced in a processing chamber. At least one heating element extends along a longitudinal axis of the elongate enclosure through an open interior region allowing a flow of gases to pass the heating element in a direction substantially perpendicular to the longitudinal axis. Methods of processing substrates using a heating element to excite gaseous precursor species are also described.

### CROSS-REFERENCE TO RELATED APPLICATIONS

This application claims priority to U.S. Provisional Application No. 61/579,762, filed Dec. 23, 2011.

### BACKGROUND

Embodiments of the invention generally relate to apparatus and methods for depositing materials. More specifically, embodiments of the invention are directed to a heating element assembly for exciting gaseous species before contacting a substrate surface and atomic layer deposition chambers with a heating element.

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 0.07 μm and aspect ratios of 10 or greater. Accordingly, conformal deposition of materials to form these devices is becoming increasingly important.

During an atomic layer deposition (ALD) process, reactant gases are sequentially introduced into a process chamber containing a substrate. Generally, a first reactant is introduced into a process chamber and is adsorbed onto the substrate surface. A second reactant is then introduced into the process chamber and reacts with the first reactant to form a deposited material. A purge step may be carried out between the delivery of each reactant gas to ensure that the only reactions that occur are on the substrate surface. The purge step may be a continuous purge with a carrier gas or a pulse purge between the delivery of the reactant gases.

There is an ongoing need in the art for apparatuses and methods of rapidly and efficiently processing substrates by atomic layer deposition.

### SUMMARY

Embodiments of the invention are directed to assemblies for heating a gas during a vapor deposition reaction in a deposition processing chamber, the assemblies comprising an elongate enclosure and a heating element. The elongate enclosure has a longitudinal axis, the enclosure comprises a material resistant to thermal expansion at temperatures experienced in a processing chamber. The enclosure has an open interior region to allow a flow of gases to pass through the enclosure in a direction substantially perpendicular to the longitudinal axis. The heating element extends along the longitudinal axis from a first end of the elongate enclosure to a second end of the elongate enclosure. The heating element comprises a material to be heated by electrical current and to heat gas flowing through the enclosure during the vapor deposition reaction.

In some embodiments, the heating element comprises a portion that extends beyond one or more of the first end and second end of the elongate enclosure and the extended portion acts as an electrical lead. In one or more embodiments, the enclosure further comprises at least one connection at one or more of the first end and second end of the elongate enclosure and the connection is in electrical contact with the wire and acts as an electrical lead. In detailed embodiments, the at least one connection does not substantially increase in temperature with application of electrical current to the heating element. In certain embodiments, the enclosure is made of a material comprising quartz. In specific embodiments, the enclosure is made from a material comprising ceramic.

In specific embodiments, the heating element comprises tungsten. In some embodiments, the heating element extends from the first end of the enclosure to the second end of the enclosure in a substantially straight path. In detailed embodiments, the heating element extends from the first end of the enclosure to the second end of the enclosure in a helical path. In detailed embodiments, the heating element comprises a metal wire encapsulated in quartz.

Some embodiments further comprise at least one additional heating element extending from at least the first end of the elongate enclosure to at least the second end of the elongate enclosure and the at least one additional heating element comprises a material suitable for heating by electrical current.

In one or more embodiments, the elongate enclosure is sized to fit within a gas port of a gas distribution plate in the processing chamber. In some embodiments, the elongate enclosure is attached to a front face of a gas distribution plate so that a flow of gas from a gas port within the gas distribution plate passes through the open interior region of the assembly and the assembly does not substantially interfere with a flow of gas from an adjacent gas port.

Additional embodiments of the invention are directed to gas distribution plates comprising an input face and an output face. The input face comprises a first precursor gas input to receive a flow of a first precursor gas and a second precursor gas input configured to receive a flow of a second precursor gas. The output face has a plurality of elongate gas ports configured to direct flows of gases toward a substrate adjacent the output face. The elongate gas ports include at least one first precursor gas port and at least one second precursor gas port. The at least one first precursor gas port in flow communication with the first precursor gas and the at least one second precursor gas port in flow communication with the second precursor gas. An assembly, as described, is positioned so that a flow of gas within at least one of the first precursor gas port and the second precursor gas port passes through the open interior region in a direction substantially perpendicular the longitudinal axis of the assembly. The assembly connected to a power source configured to provide electrical current to the heating element.

In detailed embodiments, the assembly is positioned within at least one gas port. In specific embodiments, the assembly is attached to the output face of the gas distribution plate so gas flowing from a gas port passes through the open interior region of the assembly and the elongate enclosure does not substantially interfere with the flow of gases from adjacent gas ports. In certain embodiments, providing electrical current to the heating element heats the heating element to excited species in gas flowing across the thermal element and the elongate enclosure does not substantially expand.

Further embodiments of the invention are directed to assemblies for heating a gas during a vapor deposition reaction in a deposition processing chamber, the assemblies comprising an elongate enclosure and at least one heating element. The elongate enclosure comprises a material resistant to thermal expansion at temperatures experienced in a processing chamber. The elongate enclosure extends along a longitudinal axis and has an open interior region to allow a flow of gas to pass through the open interior region in a direction substantially perpendicular to the longitudinal axis and the elongate enclosure sized to fit within a channel of a gas distribution plate in the processing chamber. The at least one heating element extends along the longitudinal axis from a region beyond a first end of the elongate enclosure through the open interior region to a region beyond a second end of the elongate enclosure. The at least one heating element comprises a material suitable for heating by electrical current and the portions of the heating element in the region beyond the first end of the elongate enclosure and beyond the second end of the elongate enclosure act as electrical leads. In detailed embodiments, the heating element can be heated to excite species in a gas flowing through the open interior region.

Additional embodiments of the invention are directed to methods of processing a substrate in a processing chamber. A substrate having a surface is moved laterally beneath a gas distribution plate comprising a plurality of elongate gas ports including at least one first precursor gas port to deliver a first precursor gas and at least one second precursor gas port to deliver a second precursor gas. The first precursor gas is delivered to the substrate surface. The second precursor gas is delivered to the substrate surface. Power is applied to at least one heating element positioned within an elongate enclosure. The at least one elongate enclosures comprise a material resistant to thermal expansion at temperatures experienced in the processing chamber. The at least one elongate enclosures is positioned so that gas from a gas port passes through an open interior region of the elongate enclosure in a direction substantially perpendicular to a longitudinal axis of the elongate enclosure and gaseous species are excited so that the excited species react with the surface of the substrate.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic cross-sectional side view of an atomic layer deposition chamber according to one or more embodiments of the invention;

FIG. 2 shows a perspective view of a susceptor in accordance with one or more embodiments of the invention;

FIG. 3 shows a perspective view of a gas distribution plate in accordance with one or more embodiments of the invention;

FIG. 4 shows a front view of a gas distribution plate in accordance with one or more embodiments of the invention;

FIG. 5 shows a front view of a gas distribution plate in accordance with one or more embodiments of the invention;

FIG. 6 shows a perspective view of a wire enclosure for use with gas distribution plates in accordance with one or more embodiments of the invention;

FIG. 7 shows a view of an assembly in accordance with one or more embodiments of the invention;

FIG. 8 shows a view of an assembly in accordance with one or more embodiments of the invention;

FIG. 9 shows a view of an assembly in accordance with one or more embodiments of the invention;

FIG. 10 shows a view of an assembly in accordance with one or more embodiments of the invention;

FIG. 11 shows a cross-sectional view of a gas distribution plate in accordance with one or more embodiments of the invention; and

FIG. 12 shows a cross-sectional view of a gas distribution plate in accordance with one or more embodiments of the invention.

### DETAILED DESCRIPTION

Embodiments of the invention are directed to assemblies with heating elements and atomic layer deposition apparatus and methods which provide excited gaseous species for reaction with the substrate surface using the heating element assemblies. As used in this specification and the appended claims, the terms “heating element” and “hot wire” are often used interchangeably and use of “hot wire” should not be taken as being limited to a wire. Embodiments of the invention may be implemented into ALD and other deposition processes. In some “hot wire” applications, a spring is used to control the tension of the hot wire which could be very unreliable due to the high temperatures. Various embodiments of the invention incorporate a temperature insulated container to contain and support the heating element, thus eliminating the need for tensioning and space constraints.

One or more embodiments of the invention are directed to temperature insulated containers, also referred to as enclosures, using, for example, quartz or ceramic materials to insulate the temperature from the heating element to adjacent materials. It also provides support for the heating element to prevent sagging due to high temperature. Power for the heating element can be provided through both ends of the container (enclosure) and gas enters the enclosure evenly, passing through the heating element region, creating needed radicals for ALD processes, then these radicals go through the bottom opening which can be either fully open or perforated holes, onto the wafer surface and perform the work. It may enhance the deposition or use to etch off deposition. An advantage to embodiments of the invention is to eliminate the sagging of the heating element and tensioning reliability issues due to high temperature and temperature variations. While embodiments of the invention are described with respect to ALD processes, it should be understood that the various embodiments of the invention may also be applicable to other processing methods.

As used in this specification and the appended claims, the term “exited gaseous species” means any gaseous species not in the ground electronic state. For example, molecular oxygen may be excited to form oxygen radicals, with the oxygen radicals being the excited species. Additionally, the terms “excited species”, “radical species,” and the like, are intended to mean a species not in the ground state. As used in this specification and the appended claims, the term “substrate surface” means the bare surface of the substrate or a layer (e.g., an oxide layer) on the bare substrate surface.

Some embodiments of the invention relate to the implementation of heating element technology to spatial atomic layer deposition. In traditional applications, either globally elevated temperature or plasma (e.g., DC, RF, microwave) technologies were used. According to one or more embodiments, the implementation of hot wire technology creates a localized high temperature during an ALD process. With this hot wire technology in spatial ALD processes, one or more of the temperature, power and quantity of other gases required for the process can be reduced. This reduces the cost of processing substrates and is more reliable to manufacture the process chamber and achieve higher throughput and film quality.

Generally, embodiments of the invention place a compatible material single heating element or wire, or multiple heating elements or wires, at a certain distance above the substrate. Current flowing through the wire creates a localized high temperature which can directly or indirectly excite the reactants. When the radicalized species meet the precursor, they deposit a quality film on the substrate. The heating element can be a single device such as a tubular device inserted from the front or a flange mount device mounted from the bottom. It contains all the necessary components to support the heating element, elements, wire or wires and provide current thereto.

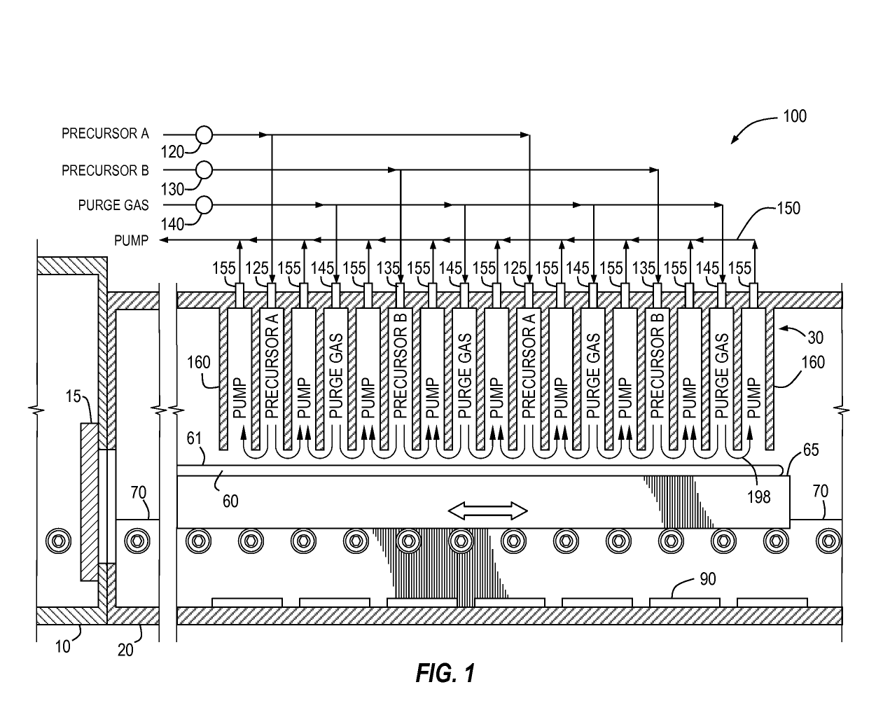

FIG. 1 is a schematic cross-sectional view of a spatial atomic layer deposition system 100 or reactor in accordance with one or more embodiments of the invention. As used in this specification and the appended claims, the term “spatial” used in respect to ALD means that the various gas streams required for the ALD reaction are separated by space rather than just time. The system 100 includes a load lock chamber 10 and a processing chamber 20. The processing chamber 20 is generally a sealable enclosure, which is operated under vacuum, or at least low pressure. The processing chamber 20 is isolated from the load lock chamber 10 by an isolation valve 15. The isolation valve 15 seals the processing chamber 20 from the load lock chamber 10 in a closed position and allows a substrate 60 to be transferred from the load lock chamber 10 through the valve to the processing chamber 20 and vice versa in an open position.

The system 100 includes a gas distribution plate 30 capable of distributing one or more gases across a substrate 60. The gas distribution plate 30 can be any suitable distribution plate known to those skilled in the art, and specific gas distribution plates described should not be taken as limiting the scope of the invention. The output face of the gas distribution plate 30 faces the first surface 61 of the substrate 60.

Substrates for use with the embodiments of the invention can be any suitable substrate. In detailed embodiments, the substrate is a rigid, discrete, generally planar substrate. As used in this specification and the appended claims, the term “discrete” when referring to a substrate means that the substrate has a fixed dimension. The substrate of specific embodiments is a semiconductor wafer, such as a 200 mm or 300 mm diameter silicon wafer.

The gas distribution plate 30 comprises a plurality of gas ports configured to transmit one or more gas streams to the substrate 60 and a plurality of vacuum ports disposed between each gas port and configured to transmit the gas streams out of the processing chamber 20. In the detailed embodiment of FIG. 1, the gas distribution plate 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 is configured to inject a continuous (or pulse) stream of a reactive precursor of compound A, a first precursor, into the processing chamber 20 through a plurality of gas ports 125. The precursor injector 130 is configured to inject a continuous (or pulse) stream of a reactive precursor of compound B, a second precursor, into the processing chamber 20 through a plurality of gas ports 135. The purge gas injector 140 is configured to inject a continuous (or pulse) stream of a non-reactive or purge gas into the processing chamber 20 through a plurality of gas ports 145. The purge gas is configured to remove reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, thereby avoiding cross-contamination between the precursors. As used in this specification and the appended claims, the terms “reactive gas”, “reactive precursor”, “first precursor”, “second precursor” and the like, refer to gases and gaseous species capable of reacting with a substrate surface or a layer on the substrate surface.

In another aspect, a remote plasma source (not shown) may be connected to the precursor injector 120 and the precursor injector 130 prior to injecting the precursors into the chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high intensity light source (e.g., UV energy), or exposure to an x-ray source. Exemplary remote plasma sources are available from vendors such as MKS Instruments, Inc. and Advanced Energy Industries, Inc.

The system 100 further includes a pumping system 150 connected to the processing chamber 20. The pumping system 150 is generally configured to evacuate the gas streams out of the processing chamber 20 through one or more vacuum ports 155. The vacuum ports 155 are disposed between each gas port so as to evacuate the gas streams out of the processing chamber 20 after the gas streams react with the substrate surface and to further limit cross-contamination between the precursors.

The system 100 includes a plurality of partitions 160 disposed on the processing chamber 20 between each port. A lower portion of each partition extends close to the first surface 61 of substrate 60. For example, about 0.5 mm or greater from the first surface 61. In this manner, the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the invention. It will be understood by those skilled in the art that the gas distribution system shown is merely one possible distribution system and the other types of showerheads may be employed.

In operation, a substrate 60 is delivered (e.g., by a robot) to the load lock chamber 10 and is placed on a shuttle 65. After the isolation valve 15 is opened, the shuttle 65 is moved along the track 70. Once the substrate 60 enters in the processing chamber 20, the isolation valve 15 closes, sealing the processing chamber 20. The shuttle 65 is then moved through the processing chamber 20 for processing. In one embodiment, the shuttle 65 is moved in a linear path through the chamber.

As the substrate 60 moves through the processing chamber 20, the first surface 61 of substrate 60 is repeatedly exposed to the precursor of compound A emitted from gas ports 125 and the precursor of compound B emitted from gas ports 135, with the purge gas emitted from gas ports 145 in between. Injection of the purge gas is designed to remove unreacted material from the previous precursor prior to exposing the substrate surface 61 to the next precursor. After each exposure to the various gas streams (e.g., the precursors or the purge gas), the gas streams are evacuated through the vacuum ports 155 by the pumping system 150. Since a vacuum port may be disposed on both sides of each gas port, the gas streams are evacuated through the vacuum ports 155 on both sides. Thus, the gas streams flow from the respective gas ports vertically downward toward the first surface 61 of the substrate 60, across the substrate surface and around the lower portions of the partitions 160, and finally upward toward the vacuum ports 155. In this manner, each gas may be uniformly distributed across the substrate surface 61. Arrows 198 indicate the direction of the gas flow. Substrate 60 may also be rotated while being exposed to the various gas streams. Rotation of the substrate may be useful in preventing the formation of strips in the formed layers. Rotation of the substrate can be continuous or in discreet steps.

The extent to which the substrate surface 61 is exposed to each gas may be determined by, for example, the flow rates of each gas coming out of the gas port and the rate of movement of the substrate 60. In one embodiment, the flow rates of each gas are configured so as not to remove adsorbed precursors from the substrate surface 61. The width between each partition, the number of gas ports disposed on the processing chamber 20, and the number of times the substrate is passed back and forth may also determine the extent to which the substrate surface 61 is exposed to the various gases. Consequently, the quantity and quality of a deposited film may be optimized by varying the above-referenced factors.

In another embodiment, the system 100 may include a precursor injector 120 and a precursor injector 130, without a purge gas injector 140. Consequently, as the substrate 60 moves through the processing chamber 20, the substrate surface 61 will be alternately exposed to the precursor of compound A and the precursor of compound B, without being exposed to purge gas in between.

The embodiment shown in FIG. 1 has the gas distribution plate 30 above the substrate. While the embodiments have been described and shown with respect to this upright orientation, it will be understood that the inverted orientation is also possible. In that situation, the first surface 61 of the substrate 60 will face downward, while the gas flows toward the substrate will be directed upward. In one or more embodiments, at least one radiant heat source 90 is positioned to heat the second side of the substrate.

The gas distribution plate 30 can be of any suitable length, depending on the number of layers being deposited onto the substrate surface 61. Some embodiments of the gas distribution plate are intended to be used in a high throughput operation in which the substrate moves in one direction from a first end of the gas distribution plate to the second end of the gas distribution plate. During this single pass, a complete film is formed on the substrate surface based on the number of gas injectors in the gas distribution plate. In some embodiments, the gas distribution plate has more injectors than are needed to form a complete film. The individual injectors may be controlled so that some are inactive or only exhaust purge gases. For example, if the gas distribution plate has one hundred injectors for each of precursor A and precursor B, but only 50 are needed, then 50 injectors can be disabled. These disabled injectors can be grouped or dispersed throughout the gas distribution plate.

Additionally, although the drawings show a first precursor gas A and a second precursor gas B, it should be understood that the embodiments of the invention are not limited to gas distribution plates with only two different precursors. There can be, for examples, a third precursor C and fourth precursor D dispersed throughout the gas distribution plate. This allows for the creation of films with mixed or stacked layers.

In some embodiments, the shuttle 65 is a susceptor 66 for carrying the substrate 60. Generally, the susceptor 66 is a carrier which helps to form a uniform temperature across the substrate. The susceptor 66 is movable in both directions (left-to-right and right-to-left, relative to the arrangement of FIG. 1) between the load lock chamber 10 and the processing chamber 20. The susceptor 66 has a top surface 67 for carrying the substrate 60. The susceptor 66 may be a heated susceptor so that the substrate 60 may be heated for processing. As an example, the susceptor 66 may be heated by radiant heat source 90, a heating plate, resistive coils, or other heating devices, disposed underneath the susceptor 66.

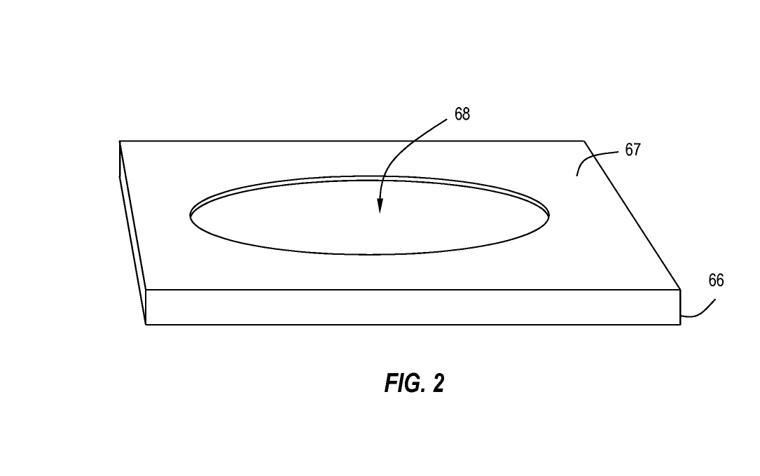

In still another embodiment, the top surface 67 of the susceptor 66 includes a recess 68 configured to accept the substrate 60, as shown in FIG. 2. The susceptor 66 is generally thicker than the thickness of the substrate so that there is susceptor material beneath the substrate. In detailed embodiments, the recess 68 is configured such that when the substrate 60 is disposed inside the recess 68, the first surface 61 of substrate 60 is level with the top surface 67 of the susceptor 66. Stated differently, the recess 68 of some embodiments is configured such that when a substrate 60 is disposed therein, the first surface 61 of the substrate 60 does not protrude above the top surface 67 of the susceptor 66.

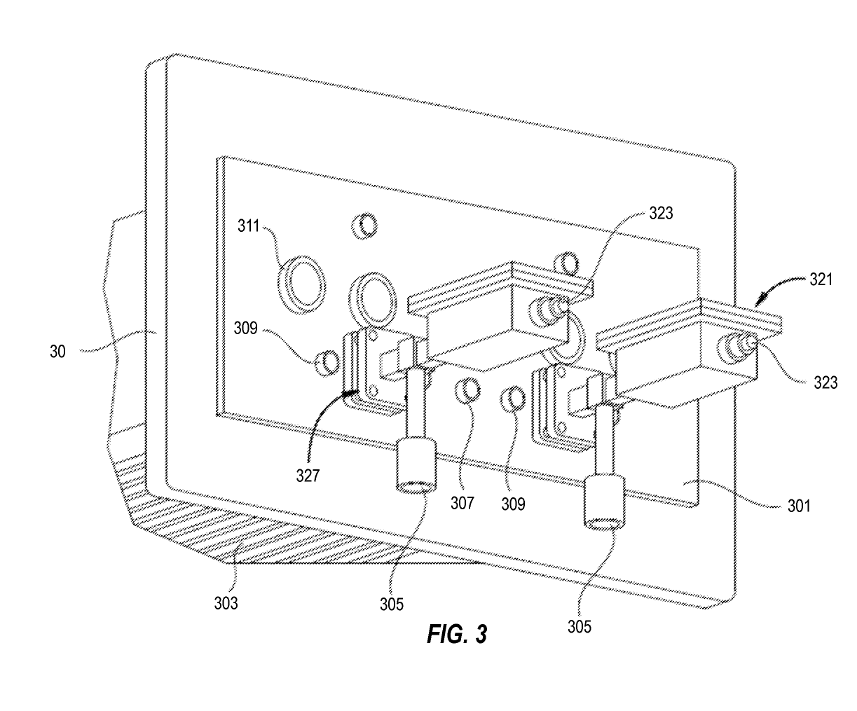

FIGS. 3-12 show gas distribution plates 30 in accordance with various embodiments of the invention. The gas distribution plates 30 comprise an input face 301 and an output face 303. The input face 301 (shown in FIG. 3) has a first precursor gas input 305 for receiving a flow of a first precursor gas A and a second precursor gas input 307 for receiving a flow of a second precursor gas B. The input face 301 also has inputs 309 for one or more purge gases and ports 311 for connecting to one or more vacuum ports. Although the configuration shown in FIG. 3 has two first precursor gas inputs 305, one second precursor gas input 307 and two purge gas inputs 309 visible, it will be understood by those skilled in the art that there can be more or less of each of these components, individually or in combination.

The specific embodiments illustrated can be used with a reciprocal deposition system in which the substrate moves back and forth adjacent the gas distribution plate to deposit multiple layers. However, it should be understood that this is merely one embodiment and that the invention is not limited to reciprocal deposition techniques. Those skilled in the art will understand that a single large gas deposition plate with multiple sets of precursor injectors can be employed.

The output face 303 of various embodiments has a plurality of elongate gas ports 313. The gas ports 313 are configured to direct flows of gases toward a substrate which may be positioned adjacent the output face 303. The elongate gas ports 313 include at least one first precursor gas port and at least one second precursor gas port. Each first precursor gas port is in flow communication with the first precursor gas input 305 to allow the first precursor to flow through the gas distribution plate 30. Each second precursor gas port is in flow communication with the second precursor gas input 307 to allow the second precursor to flow through the gas distribution plate 30.

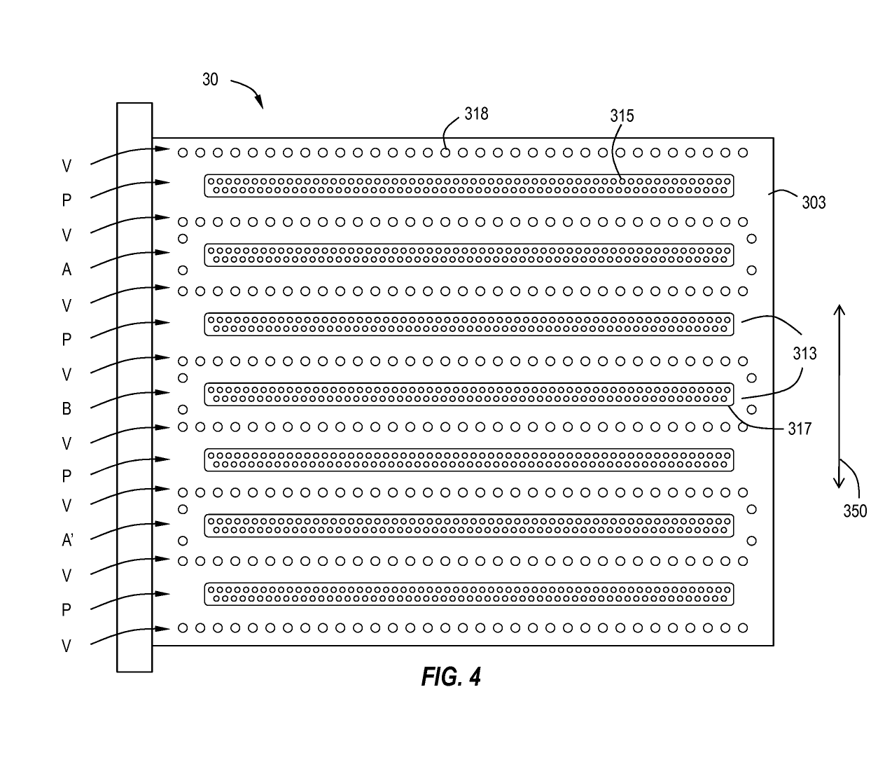

As shown in FIG. 4, the gas ports may include a plurality of openings 315 within a channel 317. The channel 317 is a recessed slot within the output face of the gas distribution plate. The gases flow out of the openings 315 and are directed by the channel 317 walls toward the substrate surface. The openings 315 are shown as being circular, but it should be understood that the openings 315 can be any suitable shape including, but not limited to, square, rectangular and triangular. The number and size of the openings 315 can also be changed to fit more or less openings within each channel 317. In the detailed embodiment shown in FIG. 4, the purge gases (P), first precursor gas ports (A) and second precursor gas ports (B) comprise a plurality of openings positioned within channels. The openings 318 associated with the vacuum ports are on the output face 303 of the gas distribution plate 30, rather than in a channel 317, but could also be positioned within a channel.

The specific embodiment shown in FIG. 4 has a combination of elongate gas ports that will provide a specific sequence of gas streams to a substrate surface when the substrate is moved perpendicularly to the elongate gas ports along arrow 350. Although the substrate is described as being moved, it will be understood by those skilled in the art that the substrate can remain stationary and the gas distribution plate 30 can move. It is the relative movement between the substrate and gas distribution plate 30 that is referred to as substrate movement. The substrate, moving perpendicularly to the elongate gas ports will be subjected to gas flows of, in order, a purge gas stream, a first precursor gas A stream, a purge gas stream, a second precursor gas B stream, a purge gas stream, a first precursor gas A′ stream and a purge gas stream. Between each of the gas streams are vacuum ports which direct the gas streams out of the processing chamber. This results in a flow pattern in accordance with arrow 198 shown in FIG. 1.

In specific embodiments, the gas distribution plate consists essentially of, in order, a leading first precursor gas port A, a second precursor gas port B and a trailing first precursor gas port A′. As used in this context, and in the appended claims, the term “consisting essentially of” means that the gas distribution plate does not include any additional gas ports for reactive gases. Ports for non-reactive gases (e.g, purge gases) and vacuum can be interspersed throughout while still being within the consisting essentially of clause. For example, the gas distribution plate 30 may have eight vacuum ports V and four purge ports P but still consist essentially of a leading first precursor gas port A, a second precursor gas port B and a trailing precursor gas port A′. Embodiments of this variety may be referred to as an ABA configuration.

The use of the ABA configuration ensures that a substrate moving from either direction will encounter a first precursor gas A port before encountering a second precursor gas B port. Each pass across the gas distribution plate 30 will result in a single film of composition B. Here, the two first precursor gas A ports surround the second precursor gas B port so that a substrate moving (relative to the gas distribution plate) from top-to-bottom of the figure will see, in order, the leading first reactive gas A, the second reactive gas B and the trailing first reactive gas A′, resulting in a full layer being formed on the substrate. A substrate returning along the same path will see the opposite order of reactive gases, resulting in two layers for each full cycle. A substrate moved back and forth across this gas distribution plate will be exposed to a pulse sequence of
AB AAB AAB (AAB)ₙ . . . AABA
   forming a uniform film composition of B. Exposure to the first precursor gas A at the end of the sequence is not important as there is no follow-up by a second precursor gas B. It will be understood by those skilled in the art that while the film composition is referred to as B, it is really a product of the surface reaction products of reactive gas A and reactive gas B and that use of just B is for convenience in describing the films.

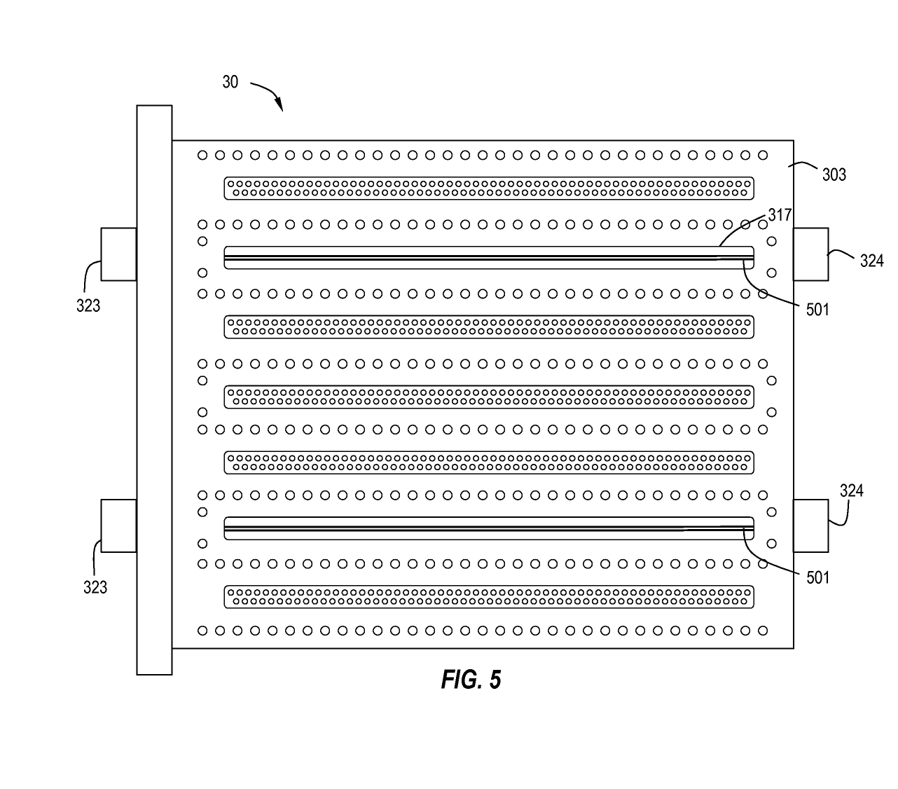

The gas distribution plate 30, as shown in FIG. 5, includes a heating element 501, which may also be referred to as a “wire” or “hot wire”, to excite gaseous species. The heating element 501 is positioned in either or both of the first precursor gas port and the second precursor gas port. The heating element 501 is connected to a power lead 323 (shown in FIG. 3) configured to cause a flow of current through the heating element 501 to heat the heating element 501. The heating element 501 is heated to high temperatures to excite the species in the gas passing adjacent the heating element 501. A purpose of the wire is to create the radical species in the gas, not to create a temperature increase in the substrate. The heating element 501 can be placed in a position in which there is no direct exposure to the surface of the substrate, while still being able to cause radical species formation in the gas. For example, if the heating element 501 is placed in the second precursor gas ports, then the element will cause a portion of the molecules in the second precursor gas to become excited. In the excited state the molecules have higher energy and are more likely to react with the substrate surface at a given processing temperature.

The placement of the heating element may have an impact on the amount of radical species contacting the substrate. Placing the heating element too far from the substrate may allow a larger number of radical species, than a closer placement, to become deactivated before contacting the substrate surface. The radical species may become deactivated by contact with other radicals, molecules in the gas stream and the gas distribution plate. However, placing the heating element further from the substrate may help prevent the heating element from heating the substrate surface while still creating radical species in the gas. The heating element 501 may be placed close enough to the surface of the substrate to ensure that excited species exist long enough to contact the surface without causing significant change in local temperature of the substrate. As used in this specification and the appended claims, the term “significant change in local temperature” means that the portion of the substrate adjacent the wire does not have an increase in temperature greater than about 10° C. The heating element 501 can be positioned in an open channel 317 like that shown in FIG. 5, or behind a gas diffusing component. An embodiment of a gas diffusing component is also shown in FIG. 5 has a plurality of small spaced apertures which are placed at the exit region of the gas port The heating element 501 can be positioned behind the gas diffusing component is capable of exciting the gaseous species without significantly changing the local temperature of the substrate. In detailed embodiments, the wire is heated to excite gaseous species while causing a surface temperature change of less than about 10° C. In various embodiments, the local change in temperature of the substrate surface is less than about 7° C., 5° C. or 3° C. In specific embodiments, the local temperature change is less than about 2° C., 1° C. or 0.5° C.

The heating element can be made of any suitable material capable of being elevated to high temperature in a relatively short period of time. A suitable material is one which is compatible with the reactive gases. As used in this specification and the appended claims, the term “compatible” used in this regard means that the heating element is not spontaneously reactive with the reactive gas at standard temperature and pressure. The temperature of the heating element may have an impact on the degree of radicalization of the gaseous species. For example, oxygen may require temperature up to about 2000° C., while polymeric species may only need temperatures in the range of about 300° C. to about 500° C. In some embodiments, the heating element is capable of being heated to a temperature of at least about 1000° C., 1100° C., 1200° C., 1300° C., 1400° C., 1500° C., 1600° C., 1700° C., 1800° C., 1900° C. or 2000° C. In various embodiments, the heating element is capable of being heated to a temperature in the range of about 300° C. to about 2000° C., or in the range of about 700° C. and about 1400° C., or in the range of about 800° C. to about 1300° C. Power supplied to the heating element can be modulated or turned on and off at any point throughout the processing. This allows the heating element to be heated, creating excited gaseous species, for only a portion of the processing.

The thickness and length of the heating element can also be changed depending on the material used. Examples of suitable materials for the heating element include, but are not limited to, tungsten, tantalum, iridium, ruthenium, nickel, chromium, graphite and alloys thereof. For example, where oxygen is the species being radicalized, the use of tantalum or tungsten may not be desired as these materials are sensitive to oxygen and may cause breakage of the wire. In detailed embodiments, the heating element comprises tungsten.

Referring back to FIG. 3, the power source can be any suitable power source capable of controlling current flow through the heating element. The power feedthrough 321 shown in FIG. 3 has a power lead 323 and provides both mechanical and electrical support for the heating element and allows the heating element to be placed in the path of the gas flow. The power feedthrough 321 is connected to the gas distribution plate 30 through a mounting block 327 which may include an insulator to electrically isolate the power lead 323 and the heating element from the gas distribution plate. The heating element in the embodiment of FIG. 3 extends through the first precursor gas channels and can be individual heating element or a single heating element which wraps around the second precursor gas channel.

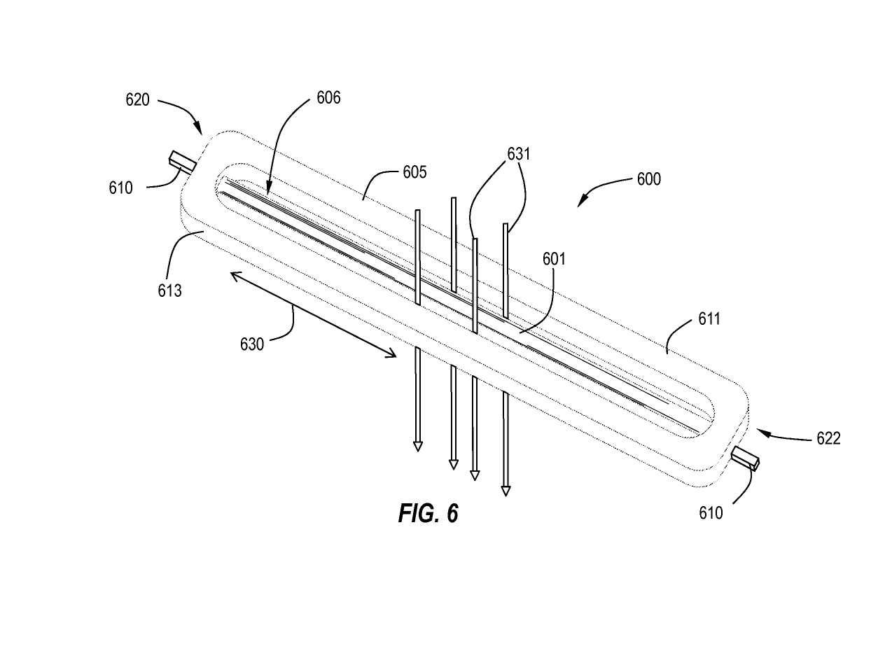

The heating element 501 shown in FIG. 5 extends through the channel 317 with the ends of the heating element 501 in contact with the power leads 323, 324. However, in one or more embodiments of the invention, the heating element is part of a separate assembly which can be inserted into the channel 317 or attached to the output face 303 of the gas distribution plate 30. Accordingly, with reference to FIG. 6, one or more embodiments of the invention are directed to such an assembly 600. The assembly 600 shown comprises an elongate enclosure 605 which extends along a longitudinal axis 630. The elongate enclosure has an open interior region 606 which can allow a flow of gases to pass through the enclosure 605. The gas flow, shown as arrows 630 can pass through the enclosure in a direction substantially perpendicular to the longitudinal axis. As used in this specification and the appended claims, the term “substantially perpendicular” means that the flow of gas passes through the enclosure and around the heating element 601 at an obtuse angle. Those skilled in the art will understand that the gas flow can be at an angle other than 90° to the enclosure and still be within the meaning of “substantially perpendicular”. In some embodiments, the gas flow is substantially perpendicular to the enclosure, forming an angle greater than about 25°, 30°, 35°, 40°, 45°, 50°, 55°, 60°, 65°, 70°, 75°, 80° or 85°. In some embodiments, the gas flow forms an angle relative to the enclosure in the range of about 25° to about 90°, or in the range of about 45° to about 90°, or in the range of about 60° to about 90°, or in the range of about 75° to about 90° or in the range of about 80° to about 90°.

The enclosure 605 shown has flat faces 611 on both sides and the sides 613 have a substantially uniform thickness from one end of the enclosure 605 to the other end. However, it will be understood by those skilled in the art that the shape and approximate dimensions shown are merely exemplary and should not be taken as limiting the scope of the invention.

The enclosure 605 is made from a material which is substantially resistant to thermal expansion at temperatures experienced in the processing chamber. As used in this specification and the appended claims, the term “substantially resistant to thermal expansion” means that the overall length of the enclosure 605 does not change by more than about 5% at temperatures required to radicalize the desired gaseous species. In various embodiments, the overall length of the enclosure does not change by more than about 4%, 3%, 2%, 1% or 0.5% relative to the length of the enclosure 605 at room temperature. In detailed embodiments, the enclosure is made of a quartz or ceramic based material, including quartz and ceramic. As used in this specification and the appended claims, the term “ceramic” refers to an inorganic, non-metallic material. Suitable examples of ceramics include, but are not limited to, alumina, beryllia, ceria, zirconia, carbides, borides, nitrides, silicides, composite materials, oxides and nonoxides of these materials. The thickness of the heating element can be uniform or varying in thickness. In some embodiments, the heating element is a wire with a cross-sectional diameter in the range of about 0.01 mm to about 5 mm. The heating element of some embodiments has a varying density/unit length.

A heating element 601 extends from a first end 620 to a second end 622 of the elongate enclosure 605. As has been described, the heating element 601 comprises a material suitable for heating by electrical current. The embodiment shown in FIG. 6 includes at least one electrical lead 610, shown as two leads, in electrical communication, or electrical contact, with the heating element 601 to allow current flow through the heating element 601. The electrical leads 610 can interact with electrical contacts positioned on the gas distribution plate. For example, pairs of electrical contacts (positive and negative contacts) can be included in the channels of the gas distribution plate or on the surface of the gas distribution plate. Each of these electrical contact pairs can be powered individually or as one or more units. In detailed embodiments, the at least one electrical lead 610 does not substantially increase in temperature with application of electrical current to the heating element. In specific embodiments, the at least one electrical lead 610 does not substantially result in expansion of the enclosure 605.

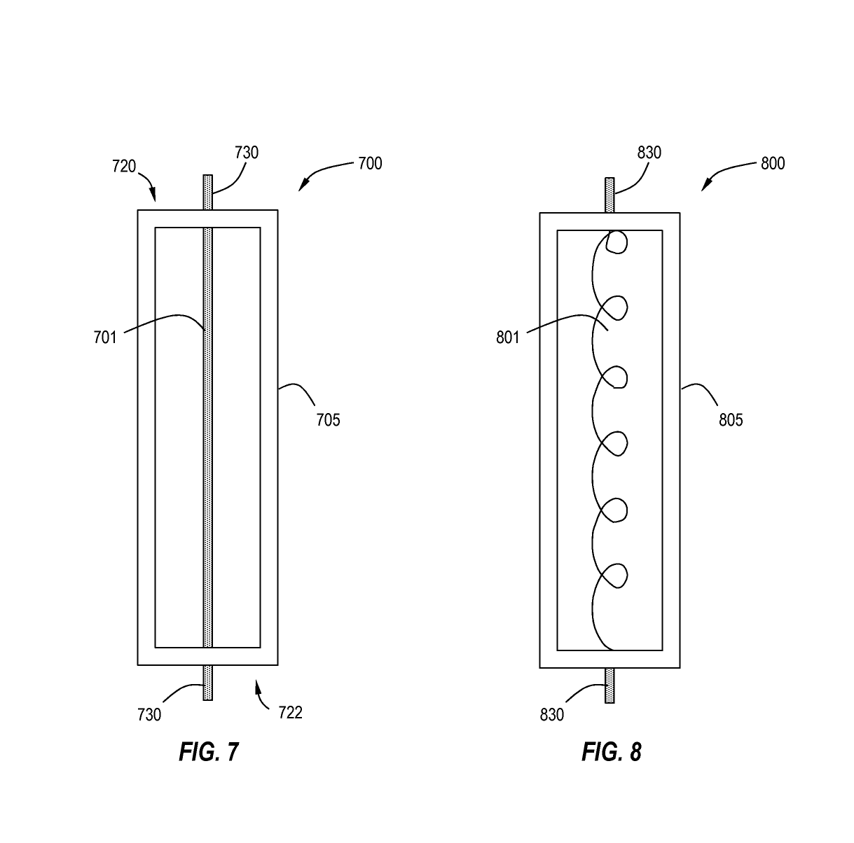

Although two separate electrical leads 610 are shown in FIG. 6, is will be understood that there can be only one electrical lead 610 positioned on either end of the enclosure. In embodiments, of this sort, the heating element 601 may extend through the enclosure 605 and present a portion that extends beyond the end of the enclosure. For example, FIG. 7 shows an embodiment of an assembly 700 in which the heating element 701 comprises a portion 730 that extends beyond one or more of the first end 720 and the second end 722 of the elongate enclosure 705. The extended portion 730 can act as an electrical lead.

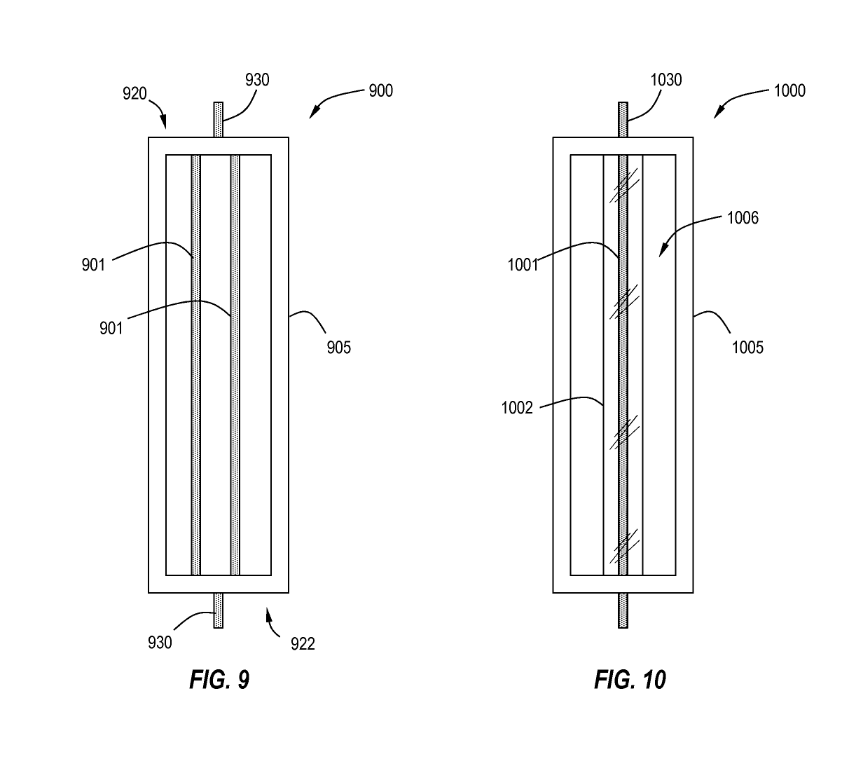

The heating element can have any suitable shape and is not limited to the shapes embodied by the drawings. Suitable shapes include, but are not limited, straight, sinusoidal, helical, curved, accordion and square-wave shaped. In detailed embodiments, as shown in FIG. 7, the heating element extends 701 from the first end 720 to the second end 722 of the enclosure 705 in a substantially straight path. FIG. 8 shows another embodiment of an assembly 800 in which the heating element 801 extends in a helical path. The number of turns and the tightness of the helix can be varied and should not be taken as limited to the shape shown in the figures. FIG. 9 shows another assembly 900 in which there are two heating elements 901 extending between the first end 920 and the second end 922 of the enclosure 905. FIG. 9 shows a single extension 930 for each end of the heating element 901 in electrical connection with the heating elements, but it will be understood that there can be an extension for each heating element 901. Additionally, there can be any number of individual heating elements and it will be understood that the shape of each element can be different, with mixtures of shapes possible.

FIG. 10 shows another embodiment of an assembly 1000 in which the heating element 1001 is encapsulated in an outer housing 1002. Upon application of current, the heating element 1001 increases temperature and heats the outer housing 1002. The outer housing 1002 being exposed to the gas flowing through the interior region 1006 of the enclosure. Embodiments of this sort may be of particular use where the heating element 1001 is incompatible with the gas flowing through the interior region 1006. In detailed embodiments, the outer housing 1002 is a material capable of being heated by the heating element 1001 without becoming deformed. In specific embodiments, the outer housing 1002 comprises quartz.

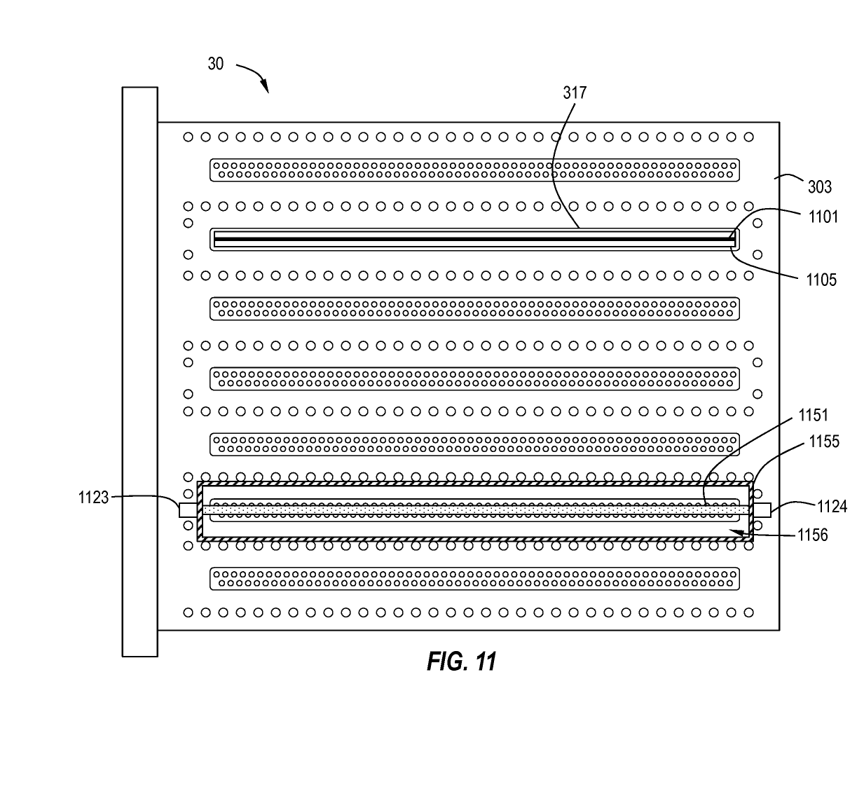

The assemblies of various embodiments can be sized to fit within the channels of a gas distribution plate so that the heating element can be easily added or removed from the gas distribution plate. FIG. 11 shows an embodiment where the elongate enclosure 1105 is sized to fit within a gas port of the gas distribution plate 30. Incorporating the heating element 501 into the enclosures 1000 allows the heating element 501 to be easily removed from the processing chamber to be replaced or cleaned. While the embodiment shown has an open channel 317, it will be understood that there can be a diffuser between the heating element and the substrate.

Referring to the bottom portion of FIG. 11, there is another embodiment shown where the elongate enclosure 1155 is configured to be attached to a front face 303 of a gas distribution plate 30. The enclosure 1155 can be positioned such that gas from a gas port passes through the open interior region 1156 of the enclosure 1155 and the assembly does not substantially interfere with a flow of gas from an adjacent gas port. The enclosure 1155 is powered by connections 1123, 1124 as described above.

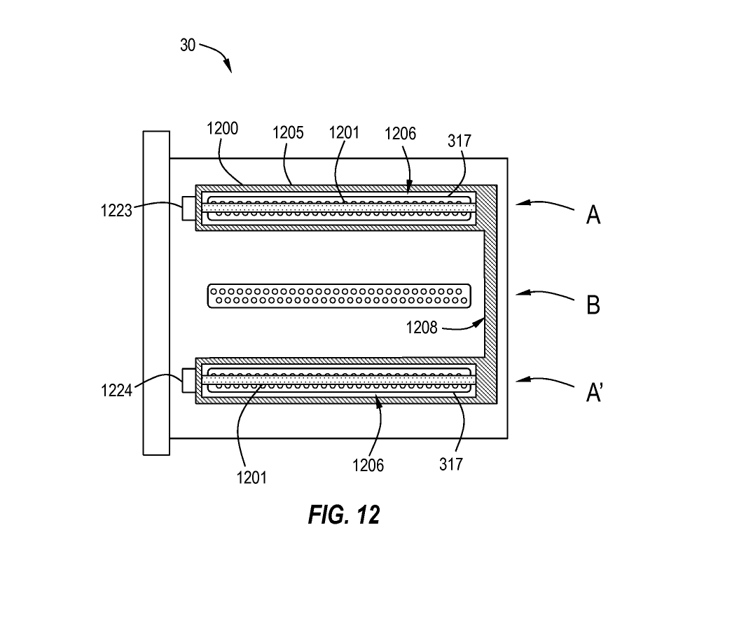

The heating elements shown in FIG. 12 are shown as straight assemblies. However, the shape of the assembly can be changed depending on the desired use. FIG. 12 shows another embodiment of the invention in which the assembly 1200 covers two channels 317 with a single heating element 1201. The assembly 1200 comprises an elongate enclosure 1205 with two open interior regions 1206 positioned over the channels 317. The heated element 1201 is connected to power leads 1223, 1224. The heated element 1201 of this embodiment can turn through the enclosure 1205 in an insulated portion 1208 where the heated element 1201 is not exposed to gas flows. In some embodiments, the heated element 1201 is exposed throughout the entire path. Stated differently, the open interior region can match the shape of the enclosure with portions of the heated element 1201 not positioned in front of gas ports.

In embodiments of the sort shown in FIG. 12, the power leads 1223, 1224 are of opposite polarity to allow current flow. Therefore, one power lead will be positive and other negative. This configuration may be relatively easy to setup, with a single power source being connected to both of the power leads 1223, 1224. The single power source (not shown) may include a mechanism to control the current flowing through the wire, such as a potentiometer.

Some embodiments of the gas distribution plate comprise a plurality of elongate gas ports consisting essentially of, in order, at least two repeating units of alternating first precursor gas A ports and second precursor gas B ports followed by a trailing first precursor gas A′ port. Stated differently, a combination of a first precursor gas A port and a second precursor gas B port, which may be referred to as an AB unit, is repeated at least two times, with a trailing first precursor gas A′ port. Those skilled in the art will understand that the purge, vacuum and plurality of openings may be present in the gas distribution plate.

Some embodiments of a gas distribution plate comprise an input face, an output face and an assembly as described herein. The input face comprises a first precursor gas input configured to receive a flow of a first precursor gas and a second precursor gas input configured to receive a flow of a second precursor gas. The output face has a plurality of elongate gas ports configured to direct flows of gases toward a substrate adjacent the output face. The elongate gas ports include at least one first precursor gas port and at least one second precursor gas port. The at least one first precursor gas port in flow communication with the first precursor gas and the at least one second precursor gas port in flow communication with the second precursor gas. The assembly described is positioned so that a flow of gas within at least one of the first precursor gas port and the second precursor gas port passes through the interior region of the assembly. The assembly is connected to a power source configured to provide electrical current to the heating element. In detailed embodiments, the assembly is positioned within at least one gas port. In specific embodiments, the assembly is attached to the output face of the gas distribution plate so gas flowing from a gas port passes through the open interior region of the assembly, and the elongate enclosure does not substantially interfere with the flow of gases from adjacent gas ports. In certain embodiments, providing electrical current to the heating element heats the heating element to excited species in gas flowing across the thermal element and the elongate enclosure does not substantially expand.

Additional embodiments of the invention are directed to methods of processing a substrate in a processing chamber. The methods comprise laterally moving a substrate having a surface beneath a gas distribution plate comprising a plurality of elongate gas ports including at least one first precursor gas port to deliver a first precursor gas and at least one second precursor gas port to deliver a second precursor gas. The first precursor gas is delivered to the substrate surface. The second precursor gas is delivered to the substrate surface. Power is applied to at least one heating element positioned within an elongate enclosure. Each of the at least one elongate enclosure comprises a material resistant to thermal expansion at temperatures experienced in the processing chamber. Each of the at least one elongate enclosure is positioned so that gas from a gas port passes through an open interior region of the elongate enclosure and gaseous species are excited. The excited species react with the surface of the substrate.

The embodiment of FIG. 12 shows an ABA configuration, but could just as easily include multiple sets of AB gas injectors spanning any desired number. For example, the gas distribution plate may have 100 sets of AB gas injectors, each individually controlled, and each individually containing a heating element and power source.

One or more embodiments have two repeating AB units with a trailing first precursor gas port A′, resulting in an ABABA configuration. Accordingly, each full cycle (one back and forth movement of a substrate through the gas streams) will result in deposition of four layers of B. A gas distribution plate with an ABABABA configuration will result in the deposition of six layers of B after a full cycle. Including a trailing first precursor gas port A′ in each of these configurations ensures that a substrate moving relative to the gas distribution plate will encounter a first precursor gas port before a second precursor gas port regardless of which side of the gas distribution plate 30 the movement originates. It will be understood by those skilled in the art that there can be any number of repeating AB units in a given gas distribution plate 30. The number of repeating AB units can vary depending on the size of the gas distribution plate. In some embodiments, there are in the range of about 2 and about 128 AB units, or even greater numbers. In various embodiments, there are at least about 2, 3, 4, 5, 10, 15, 20, 25, 30, 35, 40, 45 or 50 AB units. Additionally, it will be understood by those skilled in the art that this configuration is merely illustrative and that the gas distribution plate can comprise any number of gas injectors. For example, a gas distribution plate may have 100 repeating AB units, with or without a trailing first gas port A′.

In some embodiments, the assembly is capable of providing sufficient tension to prevent significant sagging in the heating element. Additionally, the assembly is configured to provide less tension on the heating element than would be required to cause breakage. As used in this specification and the appended claims, the term “significant sagging” means that there is a sag to length ratio of less than about 0.1, or less than about 0.05, or less than about 0.01, or less than about 0.005 or less than about 0.0025. In various embodiments, the sag is less than about 4 mm over a 400 mm length, or less than about 3 mm over a 400 mm length, or less than about 2 mm over a 400 mm length, or less than about 1 mm over a 400 mm length, or less than about 4 mm over a 300 mm length, or less than about 3 mm over a 300 mm length, or less than about 2 mm over a 300 mm length, or less than about 1 mm over a 300 mm length.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. An assembly for heating a gas during a vapor deposition reaction in a deposition processing chamber, the assembly comprising:
an elongate enclosure having a longitudinal axis, the enclosure comprising a material resistant to thermal expansion at temperatures experienced in the processing chamber, the enclosure having an open interior region to allow a flow of gases to pass through the enclosure in a direction substantially perpendicular to the longitudinal axis; and
a heating element extending along the longitudinal axis from a first end of the elongate enclosure to a second end of the elongate enclosure, the heating element comprising a material to be heated by electrical current and to heat gas flowing through the enclosure during the vapor deposition reaction.

2. The assembly of claim 1, wherein the heating element comprises a portion that extends beyond one or more of the first end and second end of the elongate enclosure, the extended portion acting as an electrical lead.

3. The assembly of claim 1, wherein the enclosure further comprises at least one connection at one or more of the first end and second end of the elongate enclosure, the connection being in electrical contact with the wire and acting as an electrical lead.

4. The assembly of claim 3, wherein the at least one connection does not substantially increase in temperature with application of electrical current to the heating element.

5. The assembly of claim 1, wherein the heating element comprises tungsten.

6. The assembly of claim 1, wherein the heating element extends from the first end of the enclosure to the second end of the enclosure in a substantially straight path.

7. The assembly of claim 1, wherein the heating element extends from the first end of the enclosure to the second end of the enclosure in a helical path.

8. The assembly of claim 1, wherein the material comprises quartz.

9. The assembly of claim 1, wherein the material comprises ceramic.

10. The assembly of claim 1, wherein the heating element comprises a metal wire encapsulated in quartz.

11. The assembly of claim 1, further comprising at least one additional heating element extending from at least the first end of the elongate enclosure to at least the second end of the elongate enclosure, the at least one additional heating element comprising a material suitable for heating by electrical current.

12. The assembly of claim 1, wherein the elongate enclosure is sized to fit within a gas port of a gas distribution plate in the processing chamber.

13. The assembly of claim 1, wherein the elongate enclosure is attached to a front face of a gas distribution plate so that a flow of gas from a gas port within the gas distribution plate passes through the open interior region of the assembly and the assembly does not substantially interfere with the flow of gas from an adjacent gas port.

14. A gas distribution plate, comprising:
an input face comprising a first precursor gas input to receive a flow of a first precursor gas and a second precursor gas input to receive a flow of a second precursor gas;
an output face having a plurality of elongate gas ports to direct flows of gases toward a substrate adjacent the output face, the elongate gas ports including at least one first precursor gas port and at least one second precursor gas port, the at least one first precursor gas port in flow communication with the first precursor gas and the at least one second precursor gas port in flow communication with the second precursor gas; and
the assembly of claim 1 positioned so that a flow of gas within at least one of the first precursor gas port and the second precursor gas port passes through the open interior region in a direction substantially perpendicular to the longitudinal axis of the assembly, the assembly connected to a power source to provide electrical current to the heating element.

15. The gas distribution plate of claim 14, wherein the assembly is positioned within at least one gas port.

16. The gas distribution plate of claim 14, wherein the assembly is attached to the output face of the gas distribution plate so gas flowing from a gas port passes through the open interior region of the assembly, and the elongate enclosure does not substantially interfere with the flow of gases from adjacent gas ports.

17. The gas distribution plate of claim 14, wherein providing electrical current to the heating element heats the heating element to excited species in gas flowing across the thermal element and the elongate enclosure does not substantially expand.

18. An assembly for heating a gas during a vapor deposition reaction in a deposition processing chamber, the assembly comprising:
an elongate enclosure comprising a material resistant to thermal expansion at temperatures experienced in a processing chamber, the elongate enclosure extending along a longitudinal axis and having an open interior region to allow a flow of gas to pass through the open interior region in a direction substantially perpendicular to the longitudinal axis, the elongate enclosure sized to fit within a channel of a gas distribution plate in the processing chamber; and
at least one heating element extending along the longitudinal axis from a region beyond a first end of the elongate enclosure through the open interior region to a region beyond a second end of the elongate enclosure, the at least one heating element comprising a material suitable for heating by electrical current, the portions of the heating element in the region beyond the first end of the elongate enclosure and beyond the second end of the elongate enclosure acting as electrical leads.

19. The assembly of claim 18, wherein the heating element can be heated to excite species in a gas flowing through the open interior region.

20. A method of processing a substrate in a processing chamber, the method comprising:
laterally moving a substrate having a surface beneath a gas distribution plate comprising a plurality of elongate gas ports including at least one first precursor gas port to deliver a first precursor gas and at least one second precursor gas port to deliver a second precursor gas;
delivering the first precursor gas to the substrate surface;
delivering the second precursor gas to the substrate surface; and
applying power to at least one heating element positioned within an elongate enclosure, the elongate enclosure comprising a material resistant to thermal expansion at temperatures experienced in the processing chamber, the elongate enclosure positioned so that gas from a gas port passes through an open interior region of the elongate enclosure in a direction substantially perpendicular to a longitudinal axis of the elongate enclosure and gaseous species are excited so that the excited species react with the surface of the substrate.
